(19) United States
(12) Patent Application Publication
(10) Pub. No.: US 2013/0003897 A1
(43) Pub. Date: Jan. 3, 2013

(54) METHOD AND APPARATUS FOR DEMODULATING DOWNLINK SIGNAL IN WIRELESS COMMUNICATION SYSTEM

(75) Inventors: Jun Woo KIM, Daejeon-si (KR); Kyung Yeol Sohn, Daejeon-si (KR); Hoon Lee, Daejeon-si (KR); Youn Ok Park, Daejeon-si (KR)

(73) Assignee: ELECTRONICS AND TELECOMMUNICATION RESEARCH INSTITUTE, Daejeon-si (KR)

(21) Appl. No.: 13/458,261

(22) Filed: Apr. 27, 2012

(30) Foreign Application Priority Data
Jun. 30, 2011 (KR) 10-2011-0064163

(51) Int. Cl. H04L 27/06; H03D 1/00

(52) U.S. Cl. 375/340

(57) ABSTRACT

There is provided a method and apparatus in which a user equipment demodulates a downlink signal in a wireless communication system. The user equipment receives a first orthogonal frequency division multiplexing (OFDM) signal from a first node serving the mobile station, receives a second OFDM signal from a second node different from the first node, and demodulates the first OFDM signal and the second OFDM signal in a fast Fourier transform (FFT) section. The first OFDM signal and the second OFDM signal are either normal mode signals each having a first cyclic prefix (CP) or cooperative mode signals each having a second CP, and the second CP has a longer length than the first CP.

### CROSS-REFERENCE TO RELATED APPLICATIONS

This application claims the benefit of priority of Korean Patent application No. 10-2011-0064163 filed on Jun. 30, 2011, which is incorporated by reference.

### BACKGROUND OF THE INVENTION

1. Field of the Invention

The present invention relates to wireless communication and, more particularly, to a method and apparatus for demodulating a downlink signal in a wireless communication system.

2. Related Art

Effective transmission and reception schemes for broadband wireless communication systems and methods for utilizing the schemes have been proposed in order to maximize the efficiency of limited radio resources. One of systems taken into consideration in the next-generation wireless communication system is an orthogonal frequency division multiplexing (OFDM) system capable of attenuating an inter-symbol interference (ISI) effect with low complexity. In the OFDM system, data symbols received in series are transformed into N parallel data symbols, carried on respective subcarriers, and then transmitted. The subcarriers maintain orthogonality in the frequency dimension. The orthogonal channels experience independent frequency selective fading. Accordingly, ISI can be minimized because complexity in a receiving stage is reduced and spacing between the transmitted symbols is lengthened.

Cooperative communication may be performed in a wireless communication system. The cooperative communication method is a method in which several neighboring nodes detect signals propagated through radio channels and improve the performance of a wireless communication system by using the detected signals to the maximum extent. Nodes, such as a repeater, a small-sized femto base station, and a mobile station, can perform cooperative communication, such as simple cooperative relaying (SCR) performing only a relay function or mutually cooperative relaying (MCR) performing transmission and relay functions between the nodes.

Meanwhile, inter-symbol interference (ISI) may occur in an OFDM system. ISI is one of distortion phenomena of a signal in which one symbol and a symbol subsequent to the one symbol interfere with each other. When ISI is generated, one symbol may act as noise for a subsequent symbol. In general, ISI may be generated by multi-path propagation or a non-linear frequency response unique to a channel. ISI generates an error in the decision device of a receiving stage. Accordingly, various efforts are being made to reduce the influence of ISI.

In a cooperative communication system, a mobile station may receive signals from a plurality of nodes. The signals received from the plurality of nodes may have different delays. The intensity of a reception signal having longer propagation delay may be stronger because some of the signals may be received through a relay station (RS). Accordingly, an ISI phenomenon according to multi-path propagation may occur.

There is a need for an efficient method of reducing ISI in a cooperative communication system.

### SUMMARY OF THE INVENTION

The present invention provides a method and apparatus for demodulating a downlink signal in a wireless communication system. In particular, the present invention provides a method of selecting a downlink demodulation section so that optimal performance can be achieved according to a cooperative communication mode when a mobile station receives signals having various reception signal intensities and various propagation delays in an OFDM system in which cooperative communication is performed.

In an aspect, a method of demodulating, by a user equipment, a downlink signal in a wireless communication system is provided. The method includes receiving a first orthogonal frequency division multiplexing (OFDM) signal from a first node serving the user equipment, receiving a second OFDM signal from a second node different from the first node, and demodulating the first OFDM signal and the second OFDM signal in a fast Fourier transform (FFT) section, wherein the first OFDM signal and the second OFDM signal are either normal mode signals each having a first cyclic prefix (CP) or cooperative mode signals each having a second CP, and the second CP has a longer length than the first CP.

If the first OFDM signal and the second OFDM signal are the normal mode signals, the FFT section may be set based on a demodulation timing of the first OFDM signal.

If the first OFDM signal and the second OFDM signal are the cooperative mode signals, the FFT section may be set based on a demodulation timing of the first OFDM signal.

The method may further include whether the second OFDM signal is received anterior to the first OFDM signal.

The first OFDM signal may be received via a relay station.

If the second OFDM signal is received anterior to the first OFDM signal and the first OFDM signal and the second OFDM signal are the cooperative mode signals, the FFT section may be set based on a demodulation timing of the second OFDM signal.

If the first OFDM signal may be received anterior to the second OFDM signal or the first OFDM signal and the second OFDM signal are the normal mode signals, the FFT section is set based on a demodulation timing of the first OFDM signal.

In another aspect, a user equipment in a wireless communication system is provided. The user equipment includes a radio frequency (RF) unit configured to transmit or receive a radio signal, and a processor connected to the RF unit, wherein the processor is configured to receive a first orthogonal frequency division multiplexing (OFDM) signal from a first node serving the user equipment, receive a second OFDM signal from a second node different from the first node, and demodulate the first OFDM signal and the second OFDM signal in a fast Fourier transform (FFT) section, wherein the first OFDM signal and the second OFDM signal are either normal mode signals each having a first cyclic prefix (CP) or cooperative mode signals each having a second CP, and the second CP has a longer length than the first CP.

### BRIEF DESCRIPTION OF THE DRAWINGS

FIG. 1 shows a wireless communication system.

FIG. 2 shows a cooperative communication system.

FIG. 3 shows a relationship between the section where fast Fourier transform (FFT) is performed in an OFDM receiver and inter-symbol interference (ISI).

FIGS. 4 and 5 show the cell coverages of respective nodes according to the proposed invention.

FIG. 6 shows a change in the length of a CP according to the proposed invention.

FIG. 7 shows an embodiment of a proposed method of demodulating a downlink signal.

FIG. 8 shows an embodiment of demodulation timing according to the proposed method of demodulating a downlink signal.

FIG. 9 shows another embodiment of demodulation timing according to the proposed method of demodulating a downlink signal.

FIG. 10 shows another embodiment of the proposed method of demodulating a downlink signal.

FIG. 11 is a block diagram of a wireless communication system in which the embodiments of the present invention are implemented.

### DESCRIPTION OF EXEMPLARY EMBODIMENTS

Hereinafter, some embodiments of the present invention are described in detail with reference to the accompanying drawings in order for those skilled in the art to be able to readily implement the invention. However, the present invention may be modified in various different forms and are not limited to the following embodiments. In order to clarify a description of the present invention, parts not related to the description are omitted, and the same reference numbers are used throughout the drawings to refer to the same or like parts. Furthermore, a description of parts which may be easily understood by those skilled in the art is omitted.

In the entire specification and claims, when it is said that any element “includes (or comprises)” any element, it means the corresponding element does not exclude other elements other than the corresponding element and may further include other elements which fall within the scope of the technical spirit of the present invention.

The following technologies may be used in a variety of multiple access schemes, such as code division multiple access (CDMA), frequency division multiple access (FDMA), time division multiple access (TDMA), orthogonal frequency division multiple access (OFDMA), and single carrier frequency division multiple access (SC-FDMA). CDMA may be implemented using radio technology, such as universal terrestrial radio access (UTRA) or CDMA2000. TDMA may be implemented using radio technology, such as global system for mobile communications (GSM)/general packet radio service (GPRS)/enhanced data Rates for GSM evolution (EDGE). OFDMA may be implemented using radio technology, such as institute of electrical and electronics engineers (IEEE) 802.11 (Wi-Fi), IEEE 802.16 (WiMAX), IEEE 802.20, or evolved UTRA (E-UTRA). IEEE 802.16m is an evolution of IEEE 802.16e, and it provides backward compatibility with systems based on IEEE 802.16e. UTRA is part of a universal mobile telecommunications system (UMTS). 3^{rd} generation partnership project (3GPP) long term evolution (LTE) is part of an evolved UMTS (E-UMTS) using E-UTRA, and it adopts OFDMA in downlink and adopts SC-FDMA in uplink. LTE-advanced (LTE-A) is an evolution of LTE.

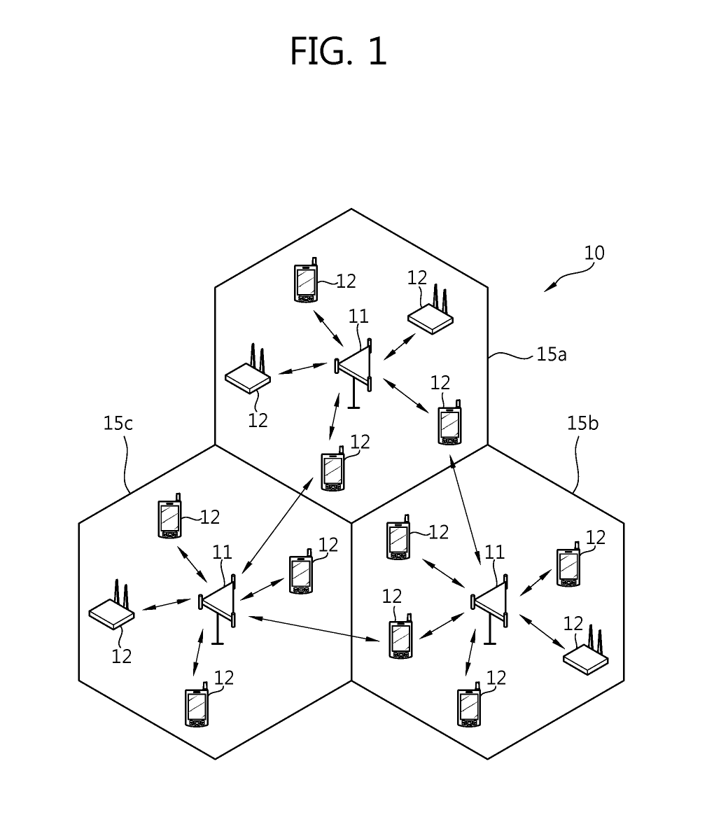

FIG. 1 shows a wireless communication system.

The wireless communication system 10 includes one or more base stations (BSs) 11. The BSs 11 provide communication services to respective geographical areas (commonly called cells) 15a, 15b, and 15c. Each of the cells may be divided into a plurality of areas (also called sectors). User equipment (UE) 12 may be fixed or mobile and may also be called another terminology, such as a mobile station (MS), a mobile terminal (MT), a user terminal (UT), a subscriber station (SS), a wireless device, a personal digital assistant (PDA), a wireless modem, or a handheld device. The BS 11 commonly refers to a fixed station communicating with the UEs 12, and it may also be called another terminology, such as an evolved NodeB (eNB), a base transceiver system (BTS), or an access point.

UE commonly belongs to one cell. The cell to which the UE belongs is called a serving cell. A BS providing the serving cell with communication service is called a serving BS. Another cell neighboring the serving cell exists because a wireless communication system is a cellular system. The cell neighboring the serving cell is called a neighbor cell. A BS providing the neighbor cell with communication service is called a neighbor BS. The serving cell and the neighbor cell are relatively determined on the basis of UE.

This technology may be used in downlink and uplink. In general, downlink refers to communication from the BS 11 to the UE 12, and uplink refers to communication from the UE 12 to the BS 11. In downlink, a transmitter may be part of the BS 11, and a receiver may be part of the UE 12. In uplink, a transmitter may be part of the UE 12, and a receiver may be part of the BS 11.

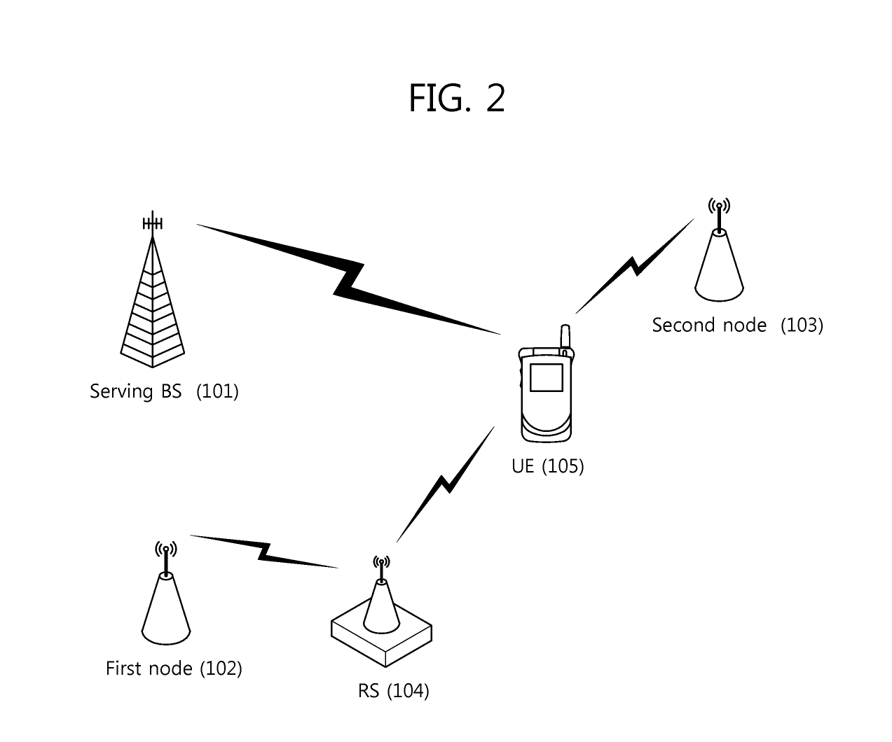

FIG. 2 shows a cooperative communication system.

Referring to FIG. 2, the cooperative communication system includes a serving BS 101, first and second nodes 102 and 103, and a relay station (RS) 104. The serving BS 101 provides communication service to UE 105. The UE 105 may directly receive a signal from the serving BS 101, directly receive a signal from the second node 103, and receive a signal from the first node 102 via the RS 104. The first node 102 or the second node 103 may be any one of a neighbor BS, a small-sized femto BS, an RS, and another UE. The UE 105 may be operated in a normal mode in which the UE 105 receives only the signal from the serving BS 101 or in a cooperative mode in which the UE 105 receives signals from a plurality of nodes.

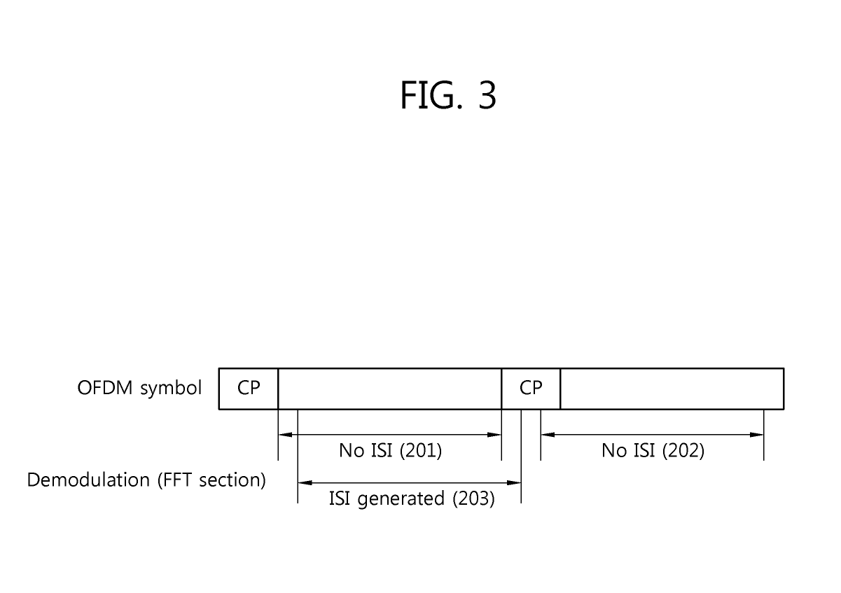

FIG. 3 shows a relationship between the section where fast Fourier transform (FFT) is performed in an OFDM receiver and inter-symbol interference (ISI).

Referring to FIG. 3, in an OFDM system, each symbol includes a cyclic prefix (CP). The CP may have a form copied from the rear part of each OFDM signal. Accordingly, ISI may be prevented by performing FFT for demodulating the OFDM signal within the CP section although the OFDM signal is received out of synchronization with the FFT section. In FIG. 3, if FFT is started within the CP section (201, 202), ISI is not generated. If FFT is started outside the CP section (203), however, ISI is occurred because a previously received symbol acts as noise for a subsequently received symbol.

In a cooperative communication system, UE may receive signals from a plurality of nodes. The signals received from the plurality of nodes may have different delays, and some of the signals may be received through an RS. For this reason, a reception signal having a longer propagation delay may have a stronger intensity. Accordingly, in order to prevent ISI, the length of the CP needs to be longer in the cooperative mode in which cooperative communication is performed than in the normal mode. Furthermore, the length of the CP needs to be flexibly changed according to a mode.

Accordingly, in a cooperative communication system, each node can change the length of the CP and the amount of transmission power according to the transmission mode, such as the normal mode or the cooperative mode. A proposed method of demodulating a downlink signal is described below in connection with embodiments.

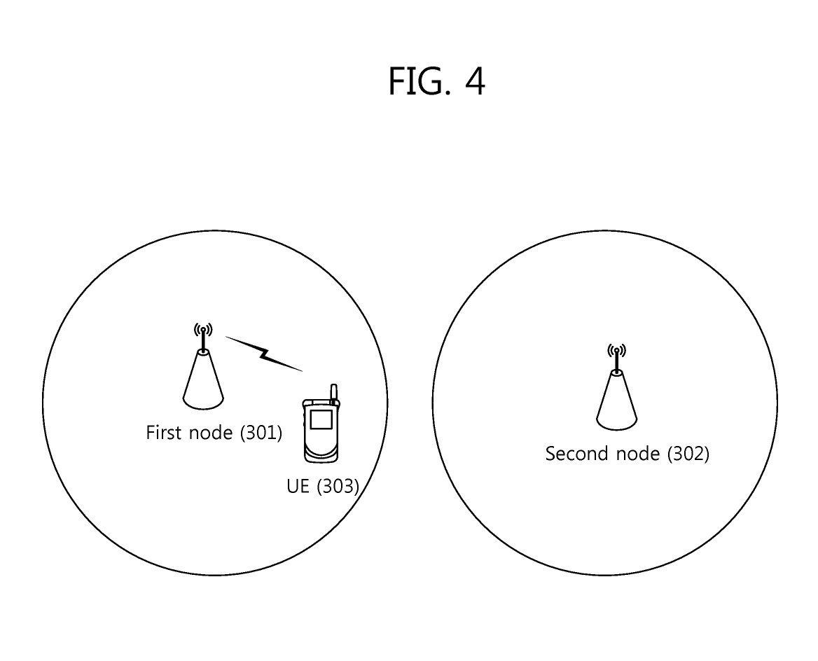

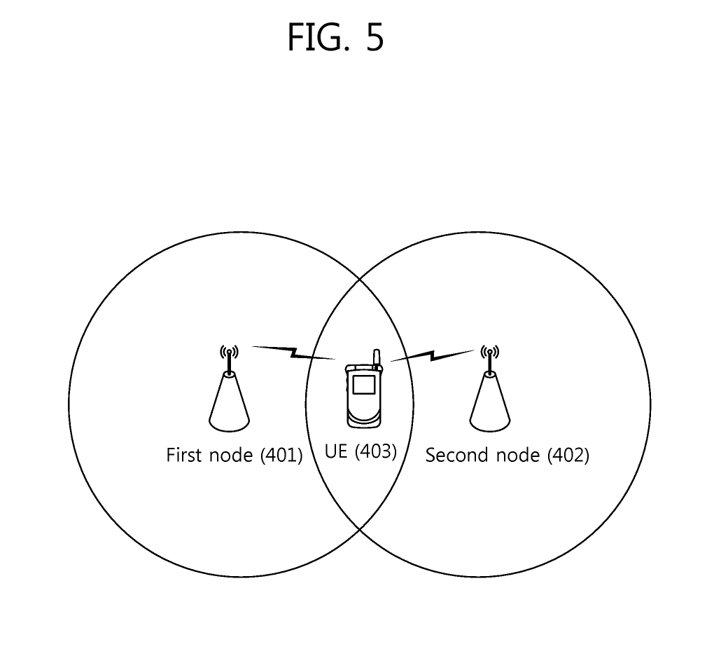

FIGS. 4 and 5 show the cell coverage of each node according to the proposed invention.

FIG. 4 shows the cell coverage of each node in the normal mode. In FIG. 4, cooperative communication is not performed between the nodes, and UE 303 receives a signal from only a first node 301 that is a serving node. In the normal mode, each of the first and the second nodes 301 and 302 can reduce the cell coverage by reducing the amount of transmission power. Accordingly, the cell coverage of the first node 301 and the cell coverage of the second node 302 may be controlled so that they do not overlap with each other. Furthermore, in the normal mode, the transmission rate may be increased by reducing the length of a CP because propagation delay is relatively small.

FIG. 5 shows the cell coverage of each node in the cooperative mode. In FIG. 5, UE 403 receives signals from a first node 401 and a second node 402. In the cooperative mode, each of the first and the second nodes 401 and 402 may increase the amount of transmission power so that the cell coverages of the first and the second nodes 401 and 402 overlap with each other. Furthermore, in the cooperative mode, reliability of a reception signal may be increased by extending the length of a CP because there is a high possibility that ISI may occur owing to propagation delay.

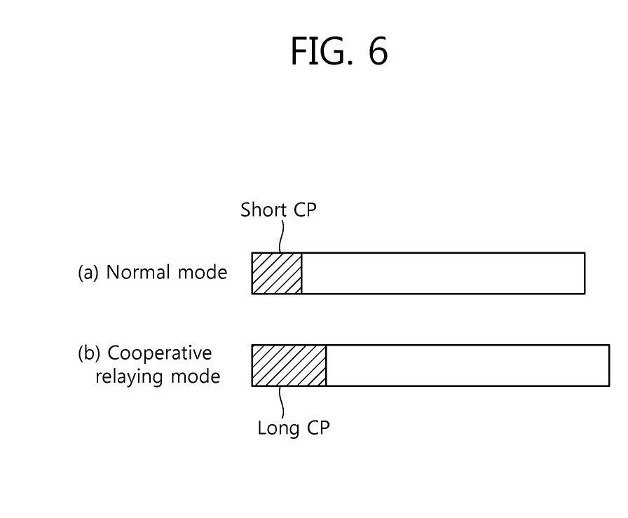

FIG. 6 shows a change in the length of a CP according to the proposed invention.

Referring to FIG. 6, an OFDM symbol in the normal mode has a short CP and thus can transmit a greater amount of data. An OFDM symbol in the cooperative mode has a relatively long CP, and thus ISI can be prevented and reliability of a reception signal can be secured.

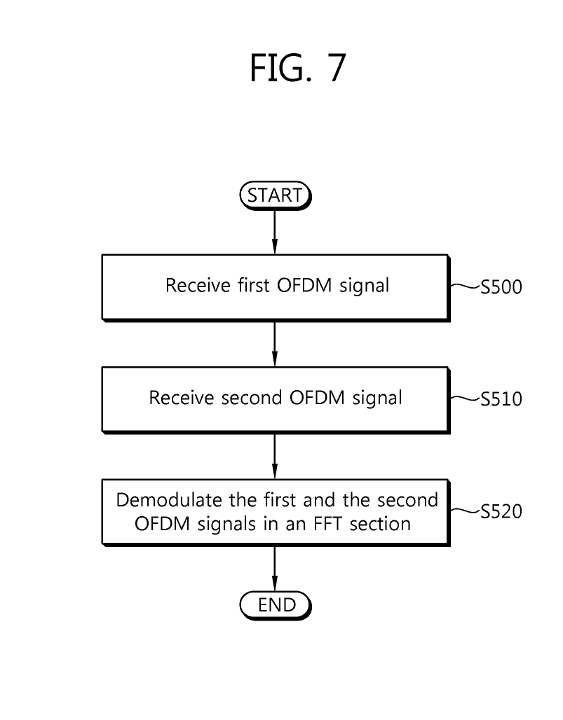

FIG. 7 shows an embodiment of a proposed method of demodulating a downlink signal.

Referring to FIG. 7, at step S500, UE receives a first OFDM signal from a first node (i.e., a serving node) from which the UE is served. At step S510, the UE receives a second OFDM signal from a second node (i.e., a node different from the first node). At step S520, the UE demodulates the first OFDM signal and the second OFDM signal in an FFT section. Here, the transmission mode of the first node and the transmission mode of the second node may be either the normal mode or the cooperative mode. In a cooperative communication system, UE may directly receive a normal mode signal from a node, directly receive a cooperative mode signal from a node, indirectly receive the normal mode signal from the node via an RS, or indirectly receive the cooperative mode signal from the node via an RS.

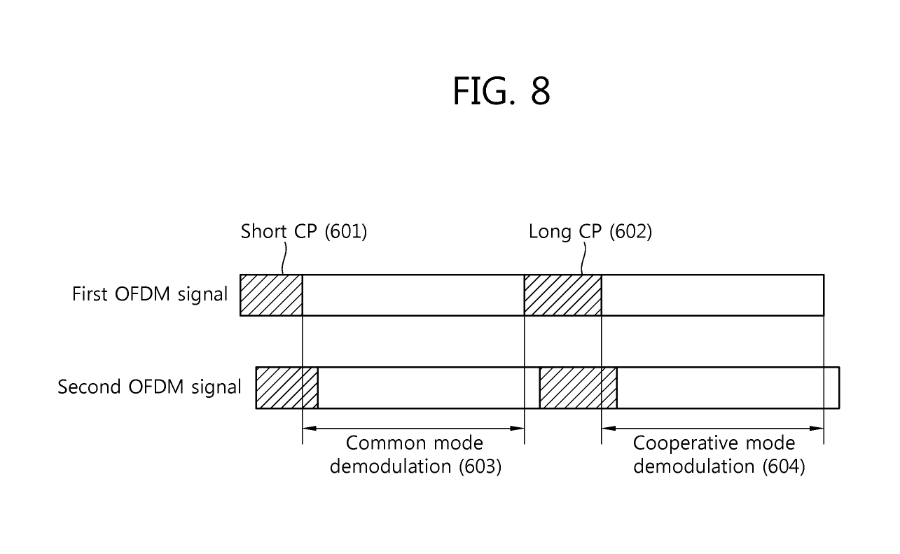

FIG. 8 shows an embodiment of demodulation timing according to the proposed method of demodulating a downlink signal.

FIG. 8 shows demodulation timing when UE directly receives a first OFDM signal from a first node and a second OFDM signal from a second node. The first node may be a serving node providing service to the UE. Each of the first OFDM signal and the second OFDM signal may include a normal mode signal having a short CP 601 and a cooperative mode signal having a long CP 602. When a signal is directly received, UE may perform demodulation by setting FFT sections 603 and 604 on the basis of the timing of the first node (i.e., a serving node), irrespective of whether the signal is a normal mode signal or a cooperative mode signal. In other words, the FFT section 603 where the normal mode signal is demodulated and the FFT section 604 where the cooperative mode signal is demodulated may be set on the basis of the timing of the first OFDM signal transmitted from the first node.

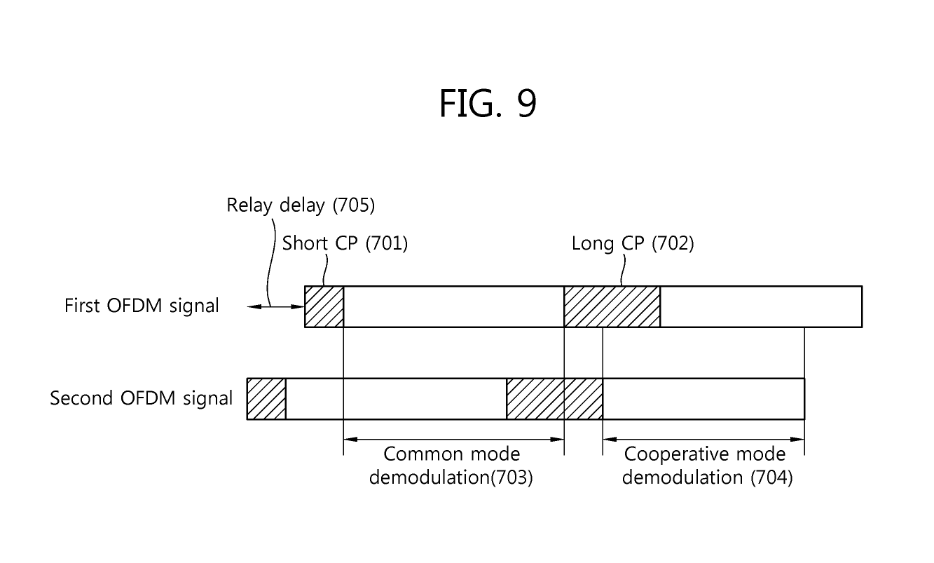

FIG. 9 shows another embodiment of demodulation timing according to the proposed method of demodulating a downlink signal.

FIG. 9 shows the demodulation timing when UE indirectly receives a first OFDM signal from a first node via an RS and directly receives a second OFDM signal from a second node. The first node may be a serving node providing the UE with service. Each of the first OFDM signal and the second OFDM signal may include a normal mode signal having a short CP 701 and a cooperative mode signal having a long CP 702. In FIG. 9, it is assumed that, when the first OFDM signal is received, a relay delay 705 due to the RS is generated because the first OFDM signal is received via the RS and the length of the relay delay 705 is longer than the length of the short CP 701. If an FFT section is set irrespective of a signal mode as in FIG. 8, ISI may occur. Accordingly, if the length of a relay delay is longer than the length of a short CP, an FFT section needs to be differently set depending on the normal mode signal and the cooperative mode signal.

For example, ISI with a previously received signal may be prevented by setting an FFT section 703 on the basis of the demodulation timing of the first node (i.e., a serving node) in demodulating the normal mode signal. Furthermore, ISI may be prevented by setting an FFT section 704 on the basis of the demodulation timing of an OFDM signal foremost received, from among OFDM signals received from a plurality of nodes, in demodulating the cooperative mode signal. In FIG. 9, it is assumed that the second OFDM signal is received anterior to the first OFDM signal. In this case, the FFT section 704 may be set on the basis of the demodulation timing of the second node in order to demodulate the cooperative mode signal. In the demodulation of the cooperative mode signal, however, the UE must know not only the reception timing of the first OFDM signal, but also the reception timing of the second OFDM signal in advance in order to set the FFT section.

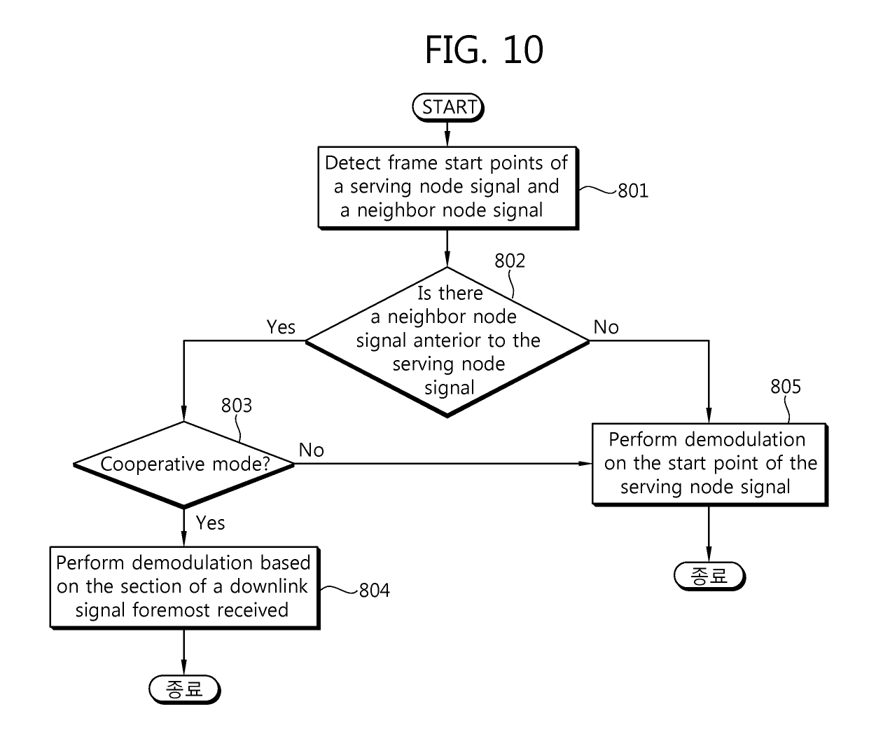

FIG. 10 shows another embodiment of the proposed method of demodulating a downlink signal.

FIG. 10 shows an embodiment of the proposed method of demodulating a downlink signal when UE indirectly receives a serving node signal from a serving node via an RS and directly receives a neighbor node signal from a neighbor node as in FIG. 9. Referring to FIG. 10, at step 801, the UE detects the frame start point of the serving node signal received from the serving node and the frame start point of the neighbor signal received from the neighbor node. At step 802, the UE determines whether the neighbor node signal anterior to the serving node signal exists. If, as a result of the determination, the serving node signal received from the serving node is posterior to the neighbor node signal in the process of being transferred via the RS, when a transmission mode is the cooperative mode, the UE sets an FFT section and performs demodulation on the basis of the timing of the neighbor node signal received anterior to the serving node signal at step 804. If, as a result of the determination, the neighbor node signal anterior to the serving node signal received from the serving node does not exist or a transmission mode is not the cooperative mode although the serving node signal is posterior to the neighbor node signal, the UE sets the FFT section and performs demodulation on the basis of the timing of the serving node signal at step 805.

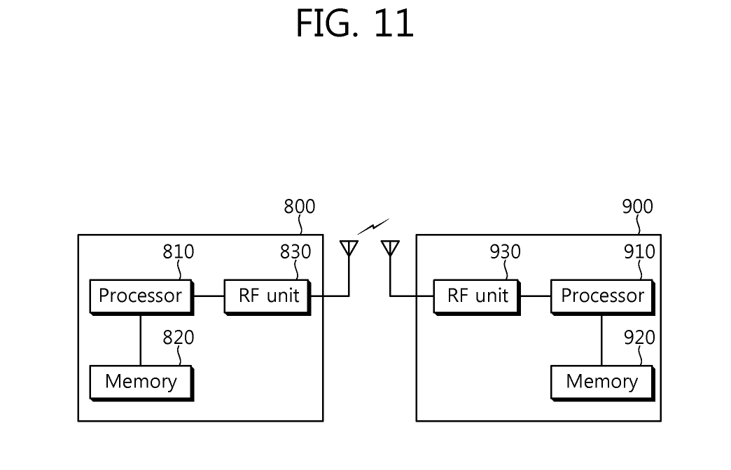

FIG. 11 is a block diagram of a wireless communication system in which the embodiments of the present invention are implemented.

A BS 800 includes a processor 810, memory 820, and a radio frequency (RF) unit 830. The processor 810 implements the proposed functions, processes, or methods or all of them. The layers of a wireless interface protocol may be implemented by the processor 810. The memory 820 is connected to the processor 810 and configured to store various pieces of information for driving the processor 810. The RF unit 830 is connected to the processor 810 and configured to transmit or receive a radio signal or to transmit and receive radio signals.

UE 900 includes a processor 910, memory 920, and an RF unit 930. The processor 910 implements the proposed functions, processes, methods, or all of them. The layers of a wireless interface protocol may be implemented by the processor 910. The memory 920 is connected to the processor 910 and configured to store various pieces of information for driving the processor 910. The RF unit 930 is connected to the processor 910 and configured to transmit and/or receive a radio signal.

The processor 810, 910 may include application-specific integrated circuits (ASICs), other chipsets, logic circuits, or data processors or all of them. The memory 820, 920 may include read-only memory (ROM), random access memory (RAM), flash memory, memory cards, storage media, or other storage devices or all of them. The RF unit 830, 930 may include a baseband circuit for processing a radio signal. When the above embodiment is implemented in software, the above scheme may be implemented using a module (process or function) for performing the above function. The module may be stored in the memory 820, 920 and executed by the processor 810, 910. The memory 820, 920 may be placed inside or outside the processor 810, 910 and connected to the processor 810, 910 using a variety of well-known means.

Cell coverage may be determined depending on whether cooperative communication is performed in accordance with the proposed method of demodulating a downlink signal. Accordingly, a plurality of nodes within a cooperative communication system can control the length of a CP through proper scheduling, and thus radio resources can be efficiently used. Furthermore, in the cooperative mode, although a signal received from a serving node, from among downlink signals received by an MS, is received with delay via an RS and both a normal mode signal and a cooperative mode signal are received, the downlink signals can be efficiently demodulated while preventing inter-symbol interference (ISI).

Consequently, ISI can be reduced in a cooperative communication system.

In the above exemplary systems, although the methods have been described on the basis of the flowcharts using a series of the steps or blocks, the present invention is not limited to the sequence of the steps, and some of the steps may be performed at different sequences from the remaining steps or may be performed simultaneously with the remaining steps. Furthermore, those skilled in the art will understand that the steps shown in the flowcharts are not exclusive and other steps may be included or one or more steps of the flowcharts may be deleted without affecting the scope of the present invention.

The above embodiments include various aspects of examples. Although all the possible combinations for describing the various aspects may not be described, those skilled in the art may appreciate that other combinations are possible. Accordingly, the present invention should be construed as including all other replacements, modifications, and changes which fall within the scope of the claims.

What is claimed is:

1. A method of demodulating, by a user equipment, a downlink signal in a wireless communication system, the method comprising:
receiving a first orthogonal frequency division multiplexing (OFDM) signal from a first node serving the user equipment;
receiving a second OFDM signal from a second node different from the first node; and
demodulating the first OFDM signal and the second OFDM signal in a fast Fourier transform (FFT) section,
wherein the first OFDM signal and the second OFDM signal are either normal mode signals each having a first cyclic prefix (CP) or cooperative mode signals each having a second CP, and
the second CP has a longer length than the first CP.

2. The method of claim 1, wherein if the first OFDM signal and the second OFDM signal are the normal mode signals, the FFT section is set based on a demodulation timing of the first OFDM signal.

3. The method of claim 1, wherein if the first OFDM signal and the second OFDM signal are the cooperative mode signals, the FFT section is set based on a demodulation timing of the first OFDM signal.

4. The method of claim 1, further comprising whether the second OFDM signal is received anterior to the first OFDM signal.

5. The method of claim 4, wherein the first OFDM signal is received via a relay station.

6. The method of claim 4, wherein if the second OFDM signal is received anterior to the first OFDM signal and the first OFDM signal and the second OFDM signal are the cooperative mode signals, the FFT section is set based on a demodulation timing of the second OFDM signal.

7. The method of claim 4, wherein if the first OFDM signal is received anterior to the second OFDM signal or the first OFDM signal and the second OFDM signal are the normal mode signals, the FFT section is set based on a demodulation timing of the first OFDM signal.

8. A user equipment in a wireless communication system, the user equipment comprising:
a radio frequency (RF) unit configured to transmit or receive a radio signal; and
a processor connected to the RF unit,
wherein the processor is configured to:
receive a first orthogonal frequency division multiplexing (OFDM) signal from a first node serving the user equipment,
receive a second OFDM signal from a second node different from the first node, and
demodulate the first OFDM signal and the second OFDM signal in a fast Fourier transform (FFT) section,
wherein the first OFDM signal and the second OFDM signal are either normal mode signals each having a first cyclic prefix (CP) or cooperative mode signals each having a second CP, and
the second CP has a longer length than the first CP.

9. The user equipment of claim 8, wherein if the first OFDM signal and the second OFDM signal are the normal mode signals, the FFT section is set based on a demodulation timing of the first OFDM signal.

10. The user equipment of claim 8, wherein if the first OFDM signal and the second OFDM signal are the cooperative mode signals, the FFT section is set based on a demodulation timing of the first OFDM signal.

11. The user equipment of claim 8, further comprising whether the second OFDM signal is received anterior to the first OFDM signal.

12. The user equipment of claim 11, wherein the first OFDM signal is received via a relay station.

13. The user equipment of claim 11, wherein if the second OFDM signal is received anterior to the first OFDM signal and the first OFDM signal and the second OFDM signal are the cooperative mode signals, the FFT section is set based on a demodulation timing of the second OFDM signal.

14. The user equipment of claim 11, wherein if the first OFDM signal is received anterior to the second OFDM signal or both the first OFDM signal and the second OFDM signal are the normal mode signals, the FFT section is set based on a demodulation timing of the first OFDM signal.
